(19) United States
(12) Patent Application Publication
(10) Pub. No.: US 2021/0407935 A1
(43) Pub. Date: Dec. 30, 2021

(54) SEMICONDUCTOR TRANSISTORS SUITABLE FOR RADIO-FREQUENCY APPLICATIONS

(71) Applicant: GLOBALFOUNDRIES U.S.INC., Santa Clara, CA (US)

(72) Inventors: WENJUN LI, Malta, NY (US); JAGAR SINGH, Malta, NY (US)

(21) Appl. No.: 16/917,802

(22) Filed: Jun. 30, 2020

(51) Int. Cl. H01L 23/66; H01L 29/78; H01L 29/66; H01L 27/092; H01L 21/8238

(52) U.S. Cl. CPC H01L 23/66; H01L 29/785; H01L 21/823821; H01L 27/0924; H01L 21/823871; H01L 29/66795

(57) ABSTRACT

A semiconductor device is provided, which includes a substrate, an active region, source and drain regions, first and second gate structures, and a contact structure. The active region is arranged over the substrate and the source and drain regions are arranged in the active region. The first and second gate structures abut upon the active region. The first gate structure is arranged between the source and drain regions and the second gate structure is arranged between the first gate structure and the drain region. The contact structure is arranged over the active region electrically coupling the first gate structure.

### FIELD OF THE INVENTION

The disclosed subject matter relates generally to semiconductor devices, and more particularly to semiconductor transistors having improved electrical performance suitable for radio-frequency (RF) applications and methods of forming the same.

### BACKGROUND

The global market for radio-frequency (RF) semiconductor devices is growing at an exponential rate. There is an increasing demand from industries such as telecommunications, radar systems, and computer networks to provide reliable and high-speed connectivity.

RF semiconductor devices, specifically the transistors for RF applications, are required to handle high-speed switching of high power RF signals. Presence of parasitic components in RF semiconductor devices, such as parasitic inductance, capacitance, conductance, and resistance, may combine to attenuate and degrade the RF signals considerably. RF signal losses are more significant at a higher operating frequency and it is critical to ensure the RF signal losses are kept low, or at least at an acceptable level, for a specific application.

Therefore, it is desirable to provide semiconductor transistors having improved electrical performance suitable for RF applications and methods of forming the same.

### SUMMARY

To achieve the foregoing and other aspects of the present disclosure, semiconductor transistors having improved electrical performance and methods of forming the same are presented.

According to an aspect of the present disclosure, a semiconductor device is provided, which includes a substrate, an active region, source and drain regions, first and second gate structures, and a contact structure. The active region is arranged over the substrate and the source and drain regions are arranged in the active region. The first and second gate structures abut upon the active region. The first gate structure is arranged between the source and drain regions and the second gate structure is arranged between the first gate structure and the drain region. The contact structure is arranged over the active region electrically coupling the first gate structure.

According to another aspect of the present disclosure, a semiconductor device is provided, which includes first and second transistors. The first and second transistors each include a first interconnect structure, a first gate structure adjacent to the first interconnect structure, a second gate structure adjacent to the first gate structure, a second interconnect structure adjacent to the second gate structure, and a contact structure. The first and second gate structures traverse across an array of active regions. The second interconnect structure is a common interconnect structure shared by the first and second transistors. The contact structure is arranged over at least one active region of the array and electrically coupling the first gate structure.

According to yet another aspect of the present disclosure, a method of forming a semiconductor device is provided, which includes providing an array of active regions over a substrate and forming a source region and a drain region in an active region of the array. The drain region is spaced apart from the source region. A first gate structure and a second gate structure are formed traversing across the array of active regions and between the source and drain regions. The first and second gate structures abut upon the array of active regions. A contact structure is formed over the active region electrically coupling the first gate structure.

### BRIEF DESCRIPTION OF THE DRAWINGS

The embodiments of the present disclosure will be better understood from a reading of the following detailed description, taken in conjunction with the accompanying drawings:

FIG. 1 is a schematic plan view of a semiconductor device, according to an embodiment of the disclosure.

FIGS. 2A to 5B are cross-sectional views of a partially processed semiconductor device, illustrating various stages of fabricating the semiconductor device, according to embodiments of the disclosure. In particular, FIGS. 2 to 5, having suffix “A” are cross-sections of the partially processed semiconductor device along a line corresponding to the section line A-A′ and the figures having suffix “B” are cross-sections of the same partially processed semiconductor device along a line corresponding to the section line B-B′, as shown in FIG. 1.

For simplicity and clarity of illustration, the drawings illustrate the general manner of construction, and certain descriptions and details of well-known features and techniques may be omitted to avoid unnecessarily obscuring the discussion of the described embodiments of the device.

Additionally, elements in the drawings are not necessarily drawn to scale. For example, the dimensions of some of the elements in the drawings may be exaggerated relative to other elements to help improve understanding of embodiments of the device. The same reference numerals in different drawings denote the same elements, while similar reference numerals may, but do not necessarily, denote similar elements.

### DETAILED DESCRIPTION

The present disclosure relates to semiconductor transistors having improved electrical performance suitable for RF applications and methods of forming the same. The transistors designed for RF applications may be preferably fabricated in a wide gate pitch region where gate structures are positioned far apart to minimize parasitic capacitance. The transistor may include a drain extension region arranged between a drain region and the gate structure to improve the breakdown voltage of the transistor. An example of a transistor having a drain extension region is a laterally-diffused metal-oxide-semiconductor (LDMOS) transistor.

Various embodiments of the present disclosure are now described in detail with accompanying drawings. It is noted that like and corresponding elements are referred to by the use of the same reference numerals. The embodiments disclosed herein are exemplary, and not intended to be exhaustive or limiting to the disclosure.

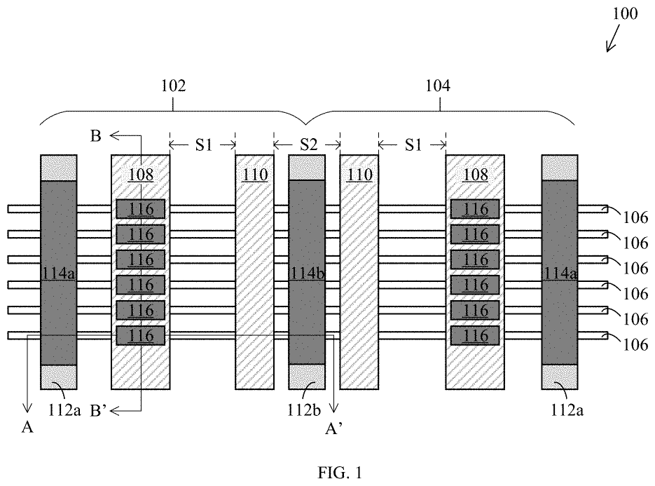

FIG. 1 is a schematic plan view of a semiconductor device 100, according to an embodiment of the disclosure. The semiconductor device 100 may be arranged in a device region of a semiconductor chip and the semiconductor device 100 may be part of a plurality of transistors arranged therein. Only a first transistor 102 and a second transistor 104 arranged adjacent to the first transistor 102 are illustrated for clarity purposes. The first and second transistors 102, 104 may be arranged over an array of active regions 106.

The array of active regions 106 may function as channels for current flow. The active regions 106 may have various shapes depending on the device architecture. For example, the active regions 106 in this embodiment are raised channels, which are shaped like fins, over a semiconductor substrate (not shown). Furthermore, it is understood that even though the active regions are represented as “fins” in the accompanying drawings, the fin is used only as a non-limiting example of the active region, and other architectural forms of the active regions (e.g., a doped layer on a top surface of a bulk semiconductor substrate or a semiconductor-on-insulator layer) may be used as well. In this embodiment of the disclosure, the array of active regions 106 is preferably fins of FinFET semiconductor devices.

The first and the second transistors 102, 104 may each include a first gate structure 108, a second gate structure 110, a plurality of interconnect structures 112a, 112b, and a plurality of contact structures 114a, 114b, 116. The first gate structure 108, the second gate structure 110, the interconnect structures 112a, 112b may be arranged such that they traverse across the array of active regions 106. The first gate structure 108 may be arranged between the interconnect structure 112a and the second gate structure 110 and the second gate structure 110 may be arranged between the first gate structure 108 and the interconnect structure 112b. In an embodiment of the disclosure, the first and second gate structures 108, 110 may include the same conductive material. In another embodiment of the disclosure, the first and second gate structures 108, 110 may include different conductive materials.

The first gate structure 108 may be separated from an adjacent second gate structure 110 by a gate spacing S1 and the second gate structure 110 may be separated from an adjacent second gate structure 110 by a gate spacing S2. The term “gate spacing,” as used herein, defines a distance between two neighboring gates. In an embodiment of the disclosure, the gate spacing S1 and S2 are substantially uniform.

It may be desirable and advantageous to form the first and second gate structures 108, 110 having substantially uniform gate spacing. There may be potential undesirable process variation during the concurrent formation of the gate structures having non-uniform gate spacing. For example, during a lithographic process to form the gate structures having different gate spacing, the lithographic tool may not be capable of simultaneously patterning the different gate spacing satisfactorily due to focusing limitations. By arranging the first and second gate structures 108, 110 substantially equidistant apart, the first and second gate structures 108, 110 may have improved printability during the concurrent formation of the gate structures.

Additionally, during a material removal process of the conductive material to form the gate structures, the material removal rate is dependent on the pattern density due to a micro loading effect. The material removal rate in a low pattern density region, i.e., in a wide gate spacing region, is higher than that in a high pattern density region, thereby resulting in non-uniformity of the gate structures. Process parameters selected in the fabrication steps may not be optimal, as compromises may be necessary to control the process variation adequately.

However, it is understood that the first and second gate structures 108, 110 may be formed separately, without departing from the spirit or scope of the disclosure. In an embodiment of the disclosure, the first gate structure 108 is an active gate structure and the second gate structure 110 is an electrically-isolated gate structure.

Due to the electrically-isolated characteristic of the second gate structure 110, the second gate structure 110 advantageously reduces the fringing capacitance between the first gate structure 108 and a drain region (not shown) of the semiconductor device 100 by providing a shield-like functionality. The reduced fringing capacitance effect minimizes the degradation of the RF signals. The second gate structure 110 further boosts the voltage handling capability of the semiconductor device 100, thereby enabling the semiconductor device 100 to achieve higher breakdown voltage. This in turn improves the electrical performance of the semiconductor device 100.

The interconnect structures 112a, 112b may be arranged such that the first and second gate structures 108, 110 are arranged therebetween and being substantially parallel to the first and second gate structures 108, 110. As will be appreciated by those skilled in the art, a neighboring transistor may share an interconnect structure of a neighboring transistor such that the transistors are mirror-images of each other. For example, as illustrated in FIG. 1, the first and second transistors 102, 104 share a common interconnect structure 112b and the second transistor 104 is a mirror-image of the first transistor 102.

In an embodiment of the disclosure, the interconnect structure 112a may be a source interconnect structure electrically coupled to a source region (not shown) in the active region 106 of the semiconductor device 100. In another embodiment of the disclosure, the interconnect structure 112b may be a drain interconnect structure electrically coupled to a drain region (not shown) in the active region 106 of the semiconductor device 100.

The contact structures 114a, 114b may be arranged over a portion of the interconnect structures 112a, 112b, respectively, that is over the array of active regions 106. The contact structures 114a, 114b may electrically couple the interconnect structures 112a, 112b, respectively, to other device regions of the semiconductor chip. The contact structures 114a, 114b may be in a form of a line-type contact structure and may be arranged over at least two active regions 106 of the semiconductor device 100.

The contact structures 116 may be arranged over a portion of the first gate structure 108 that is over the array of active regions 106. The contact structures may at least partially overlap the active region 106 for electrical coupling. The contact structures 116 provide shorter electrical paths between the first gate structure 108 and the active regions 106 and thus advantageously minimize undesirable gate resistance that may degrade RF signals. Reducing gate resistance is crucial for RF devices as the electrical performance of the RF devices is sensitive to gate resistance. The lower the gate resistance of an RF device, the higher the maximum frequency achievable, therefore realizes an RF device having improved electrical performance.

In an embodiment of the disclosure, the contact structures 116 over the first gate structure 108 may be in a form of a discrete contact structure, i.e., individual contact structures having a generally rectangular-like or cylindrical shape that couple to one active region 106.

In another embodiment of the disclosure, the contact structures 116 over the first gate structure 108 may be in a form of a line-type contact structure that traverses across at least two active regions 106 of the semiconductor device 100. The line-type contact structure further reduces the gate resistance such that a higher maximum frequency may be achievable for an optimized RF performance.

In this embodiment of the disclosure, the second gate structure 110 is electrically-isolated. For example, there is no contact structure electrically coupling the second gate structure to other device regions of the semiconductor chip.

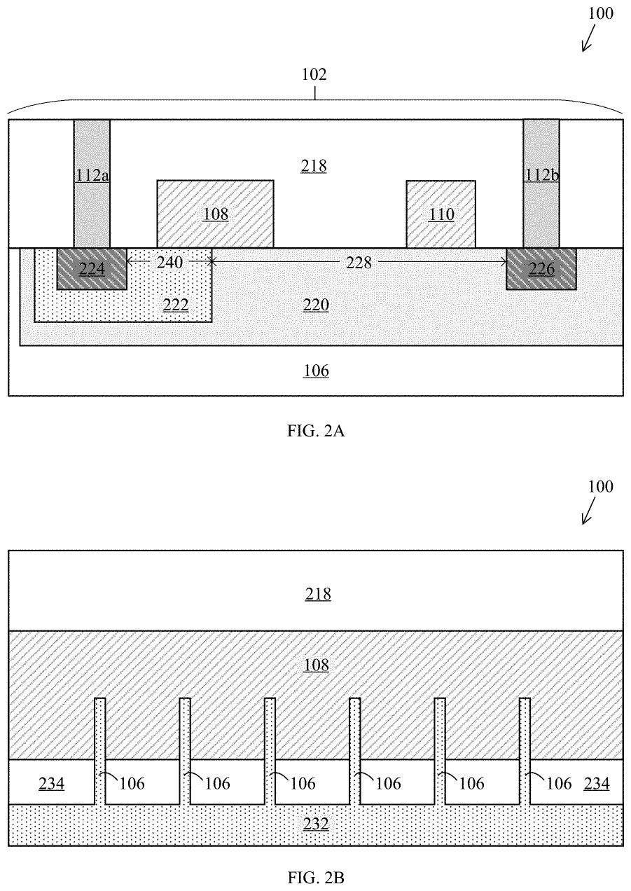

FIGS. 2A to 5B cross-sectional views of the partially processed semiconductor device 100, illustrating various stages of forming the first transistor 102, according to an embodiment of the disclosure. FIGS. 2 to 6, having suffix “A” are cross-sections of the partially processed semiconductor device 100 along a line corresponding to the section line A-A′ and the figures having suffix “B” are cross-sections of the same partially processed semiconductor device 100 along a line corresponding to the section line B-B′, as shown in FIG. 1.

As used herein, “deposition techniques” refer to the process of applying a material over another material (or the substrate). Exemplary techniques for deposition include, but not limited to, spin-on coating, sputtering, chemical vapor deposition (CVD), physical vapor deposition (PVD), molecular beam deposition (MBD), pulsed laser deposition (PLD), liquid source misted chemical deposition (LSMCD), or atomic layer deposition (ALD).

Additionally, “patterning techniques” include deposition of patterning material or photoresist, patterning, exposure, development, etching, cleaning, and/or removal of the patterning material or photoresist as required in forming a described pattern, structure or opening. Exemplary examples of techniques for patterning include, but not limited to, wet etch lithographic processes, dry etch lithographic processes or direct patterning processes. Such techniques may use mask sets.

FIGS. 2A and 2B illustrate the semiconductor device 100 after forming the first gate structure 108, the second gate structure 110, and the interconnect structures 112a, 112b, according to an embodiment of the disclosure. The first and second gate structures 108, 110 may be formed by depositing a layer of conductive material and patterning the layer of conductive material to concurrently form the first and second gate structures 108, 110.

In another embodiment of the disclosure, the first and second gate structures 108, 110 may be formed in separate fabrication steps. For example, a first layer of conductive material may be deposited over the active region 106 and the first layer of conductive material may be patterned to form the first gate structure 108 and a second layer of conductive material may be deposited over the active region 108 and patterned to form the second gate structure 110. The first and second layers of conductive materials may include the same or different conductive materials.

A dielectric layer 218 may be deposited over the active region 106; the first and second gate structures 108, 110, and the interconnect structures 112a, 112b may be encapsulated therein. The dielectric layer 218 may include, but not limited to, silicon oxide or other dielectric materials known in the art.

As illustrated in FIG. 2A, the active region 106 may include a first doped well 220, a second doped well 222, a source region 224, and a drain region 226. The first and second doped wells 220, 222 may have different dopant conductivity types, such as P-type or N-type conductivities, as well as different dopant depths and different dopant concentrations. For example, the first doped well 220 may have P-type conductivity and the second doped well 222 may have N-type conductivity or vice versa.

P-type conductivity dopants may include, but not limited to, boron, aluminum, or gallium. N-type conductivity dopants may include, but not limited to, arsenic, phosphorus, or antimony. The dopant concentrations and/or dopant depths in the active region, for example, may vary depending on the technology node and design requirements of the semiconductor device 100.

The first doped well 220 may be arranged within the active region 106 such that the source region 224 and the drain region 226 may be arranged therein. The first doped well 220 may serve as a drift well for the first transistor 102 and may have a dopant depth depending on the design requirements of the semiconductor device 100.

The first doped well 220 may include a drain extension region 228, according to an embodiment of the disclosure. The drain extension region 228 may serve to provide an electrical pathway for the diffusion of charges between the drain region 226 and a channel region 240. The drain extension region 228 may be located between the drain region 226 and second doped well 222. The length of the drain extension region 228 may vary depending on the design requirements of the semiconductor device 100.

The second doped well 222 may be arranged within the first doped well 220 such that the source region 224 may be arranged within the second doped well 222. The second doped well 222 may be further arranged such that it partially underlaps the first gate structure 108. The second doped well 222 may serve as a body well for the first transistor 102, providing an electrical pathway for the diffusion of charges between the source region 224 and the first gate structure 108. The second doped well 222 may have a dopant depth depending on the design requirements of the semiconductor device 100.

The source and drain regions 224, 226 may be formed in the active region 106 under the interconnect structures 112a, 112b, respectively. The source and drain regions 224, 226 may electrically couple their corresponding interconnect structures 112a, 112b. As described above, neighboring transistors may share an interconnect structure such that the transistors are mirror-images of each other. Accordingly, neighboring transistors may share a common source region 224 or a common drain region 226 of a neighboring transistor.

The source and drain regions 224, 226 may be formed by growing a semiconductor material in the active region 106 using a suitable epitaxy process, such as vapor-phase epitaxy process, liquid-phase epitaxy process, solid-phase epitaxy process, or other suitable epitaxy processes. The semiconductor material used to grow the source and drain regions 224, 226 may include silicon, silicon germanium, silicon phosphorous, silicon phosphorous carbide, and/or other suitable combinations. In an embodiment of the disclosure where an NMOS transistor is desired, the source and drain regions 224, 226 may include epitaxially-grown silicon. In another embodiment of the disclosure, where a PMOS transistor is desired, the source and drain regions 224, 226 may include epitaxially-grown silicon germanium.

In an alternative embodiment of the disclosure, the source and drain regions 224, 226 may be formed by doping the active region 106 with dopants. In one example, to form an NMOS transistor, the source and drain regions 224, 226 may be doped with N-type donors. The N-type donors may include phosphorus, arsenic, antimony, and/or other suitable dopants. In another example, to form a PMOS transistor, the source and drain regions 224, 226 may be doped with P-type acceptors. The P-type acceptors may include boron, aluminum, gallium, indium, and/or other suitable dopants.

The first and second gate structures 108, 110 may each include a plurality of elements such as, but not limited to, a gate electrode, a gate dielectric layer arranged between the gate electrode and the active region 106, and a pair of gate spacers arranged over sidewalls of the first and second gate structures 108, 110, although these elements are not shown in the accompanying drawings. The first gate structure 108 may be arranged between the source region 224 and the drain region 226 such that the drain region 226 is positioned further from the first gate structure 108 than that of the source region 224 to form a laterally-diffused metal-oxide-semiconductor (LDMOS) transistor. The second gate structure 110 may be arranged over the drift extension region 228 between the first gate structure 108 and the drain region 226.

In an embodiment of the disclosure, the first and second gate structures 108, 110 may be arranged over and abutting upon the plurality of active regions 106. As it is an objective of this disclosure to provide semiconductor transistors suitable for RF applications, it is desirable and preferable to keep the electrical pathway for the diffusion of charges in the drain extension region 228 as linear as possible, to minimize any degradation of RF signals due to parasitic resistance.

Although only one second gate structure 110 is illustrated in the accompanying drawings, it will be appreciated by those skilled in the art that a plurality of second gate structures 110 may be arranged between the first gate structure 108 and the drain region 226. As the second gate structures 110 are electrically-isolated gate structures that boost the voltage handling capability of a transistor, for transistors having relatively longer drain extension regions, it may be desirable to arrange more than one second gate structure 110 between the first gate structure 108 and the drain region 226. It is further desirable and preferable to form the plurality of second gate structures having substantially uniform gate spacing therebetween.

As illustrated in FIG. 2A, the first gate structure 108 has a width that is wider than the second gate structure 110. In an embodiment of the disclosure, the second gate structure 110 may have a width no wider than that of the first gate structure 108. In another embodiment of the disclosure, the first and second gate structures 108, 110 may have substantially uniform widths, although this embodiment is not shown in the accompanying drawings.

There may be potential undesirable process variation when the width of the second gate structure 110 is wider than the first gate structure 108. A wide gate structure may be susceptible to dishing concerns when fabricating the gate structures. Dishing affects the topography of the semiconductor device and may affect subsequent features that will be fabricated thereon. It may be desirable to provide more than one second gate structure of relatively narrower widths than one second gate structure having a wide width.

As illustrated in FIG. 2B, the semiconductor device 100 may include a substrate 232; the array of active regions 106 may be formed over the substrate 232. The active regions 106 are typically formed of the same semiconductor material as the substrate 232.

The first gate structure 108 may traverse across the array of active regions 106 and may be formed over top portions of the active regions 108, and an isolation layer 234 may be arranged at lower portions of the active regions between the first gate structure 108 and the substrate 232. In an embodiment of the disclosure, the isolation layer 234 is a shallow trench isolation layer.

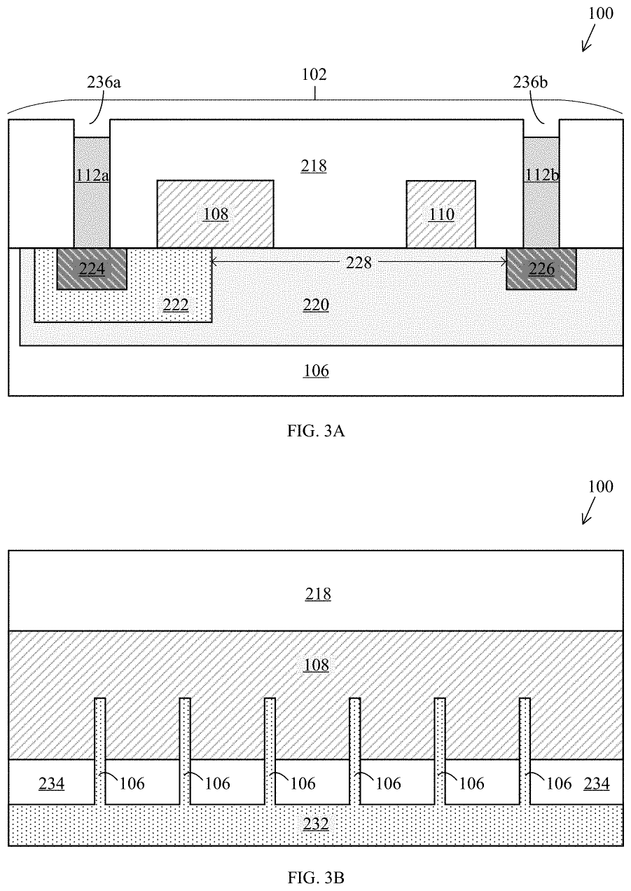

FIGS. 3A and 3B (FIG. 3A continues from FIG. 2A, and FIG. 3B continues from FIG. 2B) illustrate the semiconductor device 100 after forming a plurality of first contact openings 236a, 236b, according to an embodiment of the disclosure. The first contact opening 236a may be formed over the interconnect structure 112a and the first contact opening 236b may be formed over the interconnect structure 236b. In an embodiment of the disclosure, the first contact openings may be formed by removing a top portion of the interconnect structures 112a, 112b using a material removing process.

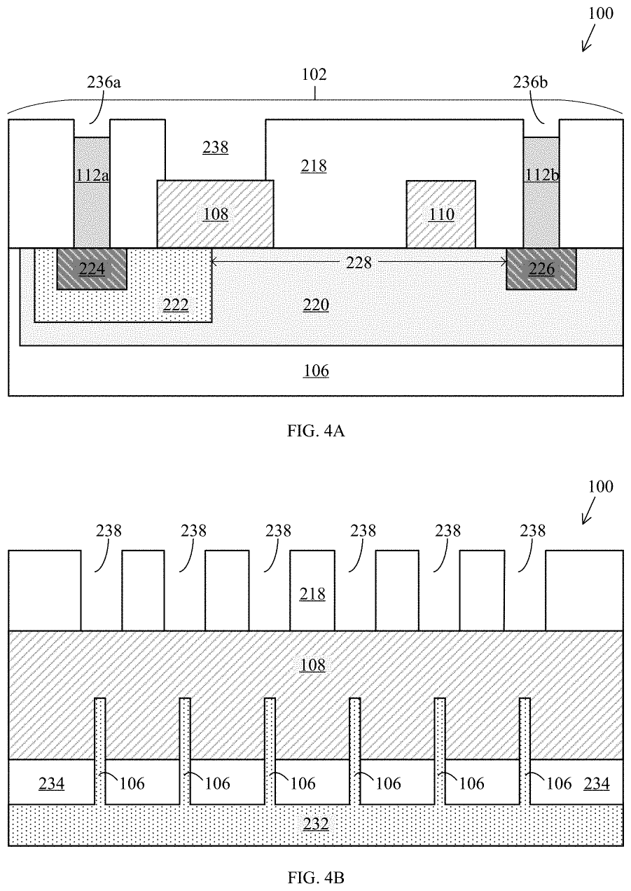

FIGS. 4A and 4B (FIG. 4A continues from FIG. 3A, and FIG. 4B continues from FIG. 3B) illustrate the semiconductor device 100 after forming a second contact opening 238 over the first gate structure 108, according to an embodiment of the disclosure. The number and configuration of the second contact openings 238 may vary depending on the design requirements of the semiconductor device 100. The second contact openings 238 may be formed by removing a top portion of the dielectric layer 218 over the first gate structure 108 to expose a portion of the first gate structure 108 in the second contact openings 238. The dielectric layer 218 may be removed using patterning and material-removing processes.

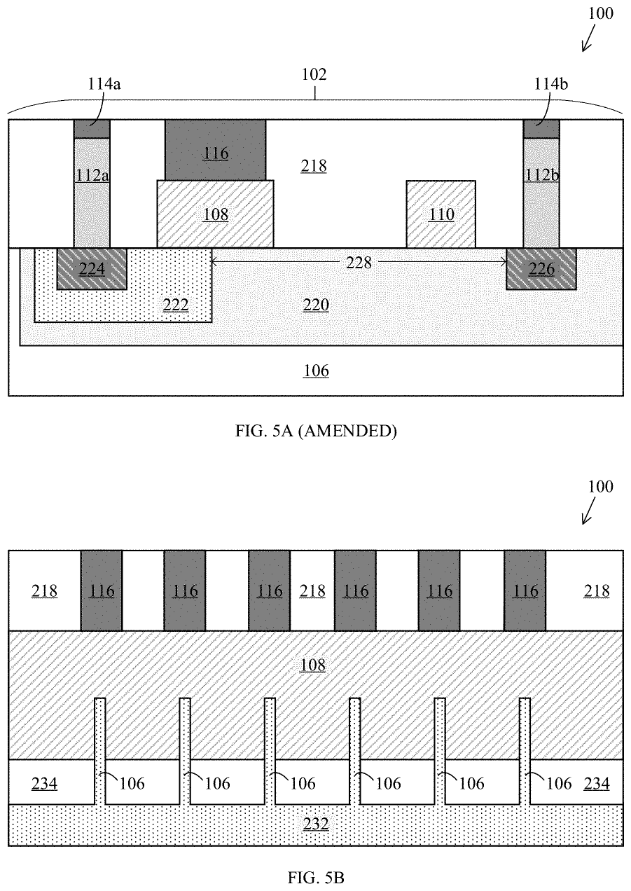

FIGS. 5A and 5B (FIG. 5A continues from FIG. 4A, and FIG. 5B continues from FIG. 4B) illustrate the semiconductor device 100 after forming a plurality of contact structures 114a, 114b, 116, according to an embodiment of the disclosure. The plurality of contact structures 114a, 114b, 116 may be formed by filling the first and second contact openings 236a, 236b, 238 with a conductive material to form the plurality of contact structures 114a, 114b, 116, using a deposition technique. A planarization process, such as a chemical mechanical planarization (CMP) process, may be employed to form a planar top surface over the plurality of contact structures 114a, 114b, 116.

Although FIGS. 2A to 5B illustrates a method of forming the first transistor 102 of the semiconductor device 100, as will be appreciated by those skilled in the art, other methods may be also employed.

For example, the first contact openings 236a, 236b may not necessarily be formed by removing top portions of the interconnect structures 112a, 112b, respectively. The first contact openings 236a, 236b may be formed by depositing a layer of dielectric material over the dielectric layer 218 and forming the first contact opening 236a over the interconnect structure 112a and the first contact opening 236b over the interconnect structure 112b by removing portions of the dielectric material.

In another example, the first contact structures 114a, 114b, 116 may not necessarily be formed of the same conductive material. The first contact openings 236a, 236b may be filled with a first conductive material and the second contact opening 238 may be filled with a second conductive material.

In yet another example, the first and second contact openings 236a, 236b, 238 may not necessarily be formed in separate processing steps and the first and second contact openings 236a, 236b, 238 may be formed concurrently.

As presented in the above disclosure, a semiconductor transistor having improved electrical performance and methods of forming the same are presented. The transistor may be a fin-type LDMOS transistor. The transistor may be arranged over an array of active regions and may include an electrically-isolated gate structure arranged over a drain extension region that is between an active gate structure and a drain region of the transistor.

The electrically-isolated gate structure advantageously reduces fringing capacitance between the active gate and the drain region of the transistor and boosts the voltage handling capability of the transistor, enabling the transistor to achieve higher breakdown voltage. This in turn improves the electrical performance of the transistor.

The transistor may further include contact structures arranged over a portion of the active gate structure that is over the array of active regions. The contact structures over the active gates provide shorter electrical paths through the active gate, thereby advantageously keeping undesirable gate resistance low.

The presence of parasitic components, such as parasitic resistance, may attenuate and degrade the RF signals considerably, especially when operating at a high frequency. The transistors disclosed herein provide significant electrical improvements to FinFET transistors, especially P-type FinFET transistors. P-type FinFET transistors are known to have higher reliability than that of N-type FinFET transistors. However, as compared to N-type FinFET transistors, P-type FinFET transistors tend to achieve lower maximum operating frequency due to an inherent higher gate resistance, which affects the overall electrical performance. By placing the contact structures over a portion of the active gate structure that is over the array of active regions and having the electrically-isolated gate structures arranged over the drain extension region, the electrical performance of P-type FinFET transistors has been significantly improved.

Having improved electrical performance, P-type FinFET transistors provide greater reliability with at least comparable electrical performance to N-type FinFET transistors, making P-type FinFET transistors attractive for use in RF applications. Furthermore, such P-type FinFET transistors having improved electrical performance provide circuit designers the design flexibility when designing RF circuitry as both P-type and N-type FinFET transistors may be implemented without compromising the electrical performance of the semiconductor chip.

The terms “top”, “bottom”, “over”, “under”, and the like in the description and in the claims, if any, are used for descriptive purposes and not necessarily for describing permanent relative positions. It is to be understood that the terms so used are interchangeable under appropriate circumstances such that the embodiments of the devices described herein are, for example, capable of operation in other orientations than those illustrated or otherwise described herein.

Additionally, the formation of a first feature over or on a second feature in the description that follows may include embodiments in which the first and second features are formed in direct contact, and may also include embodiments in which additional features may be formed interposing the first and second features, such that the first and second features may not be in direct contact.

Similarly, if a method is described herein as involving a series of steps, the order of such steps as presented herein is not necessarily the only order in which such steps may be performed, and certain of the stated steps may possibly be omitted and/or certain other steps not described herein may possibly be added to the method. Furthermore, the terms “comprise”, “include”, “have”, and any variations thereof, are intended to cover a non-exclusive inclusion, such that a process, method, article, or device that comprises a list of elements is not necessarily limited to those elements, but may include other elements not expressly listed or inherent to such process, method, article, or device. Occurrences of the phrase “in an embodiment” herein do not necessarily all refer to the same embodiment.

In addition, unless otherwise indicated, all numbers expressing quantities, ratios, and numerical properties of materials, reaction conditions, and so forth used in the specification and claims are to be understood as being modified in all instances by the term “about”.

While several exemplary embodiments have been presented in the above detailed description of the device, it should be appreciated that a number of variations exist. It should further be appreciated that the embodiments are only examples, and are not intended to limit the scope, applicability, dimensions, or configuration of the device in any way. Rather, the above detailed description will provide those skilled in the art with a convenient road map for implementing an exemplary embodiment of the device, it being understood that various changes may be made in the function and arrangement of elements and method of fabrication described in an exemplary embodiment without departing from the scope of this disclosure as set forth in the appended claims.

1. A semiconductor device, comprising:
an active region over a substrate, wherein the active region comprises a drain region spaced apart from a source region;
a first gate structure over the active region between the source region and the drain region;
a second gate structure over the active region between the first gate structure and the drain region, wherein the second gate structure is an electrically-isolated gate structure; and
a contact structure over the active region electrically coupling to the first gate structure.

2. (canceled)

3. The semiconductor device of claim 1, wherein the second gate structure has a width no wider than that of the first gate structure.

4. The semiconductor device of claim 1, wherein the contact structure at least partially overlaps the active region.

5. The semiconductor device of claim 1, wherein the active region comprises:
a first doped well, wherein the drain region is located therein; and
a second doped well within the first doped well, wherein the source region is located therein.

6. The semiconductor device of claim 5, further comprising a drain extension region in the first doped well, the drain extension region being located between the second doped well and the drain region.

7. The semiconductor device of claim 5, wherein the first doped well partially underlaps the first gate structure.

8. The semiconductor device of claim 1, wherein the first gate structure and the second gate structure comprise the same conductive material.

9. The semiconductor device of claim 1, wherein the active region is a semiconductor fin.

10. A semiconductor device, comprising:
a first transistor; and
a second transistor, the first transistor and the second transistor each comprising:
a first interconnect structure;
a first gate structure adjacent to the first interconnect structure;
a second gate structure adjacent to the first gate structure, the second gate structure is an electrically-isolated gate structure, and the first gate structure and the second gate structure traverse across an array of active regions;
a second interconnect structure, wherein the second interconnect structure is a common interconnect structure shared by the first transistor and the second transistor; and
a contact structure over an active region of the array, the contact structure electrically coupling to the first gate structure.

11. The semiconductor device of claim 10, wherein the first gate structure is arranged between the first interconnect structure and the second gate structure, and the second gate structure is arranged between the first gate structure and the second interconnect structure.

12. The semiconductor device of claim 10, wherein the second interconnect structure is arranged between the second gate structures of the first transistor and the second transistor.

13. The semiconductor device of claim 10, wherein the first gate structure and the second gate structure are separated by a substantially uniform gate spacing from an adjacent gate structure.

14. The semiconductor device of claim 10, wherein the second gate structure is part of a plurality of second gate structures arranged between the first gate structure and the second interconnect structure, and the plurality of second gate structures being separated by a substantially uniform gate spacing therebetween.

15. A method of forming a semiconductor device, comprising:
forming an array of active regions over a substrate;
forming a source region and a drain region in an active region of the array, the drain region being spaced apart from the source region;
forming a gate structure and an electrically-isolated gate structure traversing across the array of active regions and between the source region and drain region; and
forming a contact structure over the active region electrically coupling to the gate structure.

16. The method of claim 15, wherein forming the gate structure and the electrically-isolated gate structure comprises:
depositing a layer of conductive material over the array of active regions; and
patterning the layer of conductive material to form the gate structure and the electrically-isolated gate structure, the gate structure and the electrically-isolated gate structure being separated by a substantially uniform gate spacing from an adjacent gate structure.

17. The method of claim 15, wherein forming the contact structure comprises:
depositing a dielectric layer over the array of active regions, the dielectric layer encapsulating the gate structure and the electrically-isolated gate structure;
forming an opening in the dielectric layer over the array of active regions, the opening exposes the gate structure; and
filling the opening with a conductive material to form the contact structure.

18. The method of claim 17, wherein forming the opening in the dielectric layer comprises removing a portion of the dielectric layer to form a discrete opening over the first gate structure that is over the active region of the array.

19. The method of claim 17, wherein forming the opening in the dielectric layer comprises removing a portion of the dielectric layer to form a line-type opening over the first gate structure, wherein the line-type opening is over at least two active regions of the array.

20. The method of claim 16, wherein forming the gate structure and the electrically-isolated gate structure between the source region and the drain region comprises arranging the gate structure proximal to the source region such that a drain extension region is formed between the gate structure and the drain region.
